(19) United States
(12) Patent Application Publication
(10) Pub. No.: US 2026/0033050 A1
(43) Pub. Date: Jan. 29, 2026

(54) SUBMOUNT AND METHOD OF PRODUCING THE SAME, AND LIGHT-EMITTING DEVICE

(71) Applicant: Nichia Corporation, Anan-shi (JP)

(72) Inventors: Shota MURAKAMI, Anan-shi (JP); Kazuma KOZURU, Anan-shi (JP)

(73) Assignee: Nichia Corporation, Anan-shi (JP)

(21) Appl. No.: 19/274,727

(22) Filed: Jul. 21, 2025

(30) Foreign Application Priority Data
Jul. 24, 2024 (JP) 2024-118740

(51) Int. Cl. H10H 20/85; H10H 20/01; H10H 20/857

(52) U.S. Cl. CPC H10H 20/8508; H10H 20/036; H10H 20/857

(57) ABSTRACT

A submount includes: a support layer; a first graphite layer disposed on the support layer; a first metal layer disposed on the first graphite layer; and a second metal layer disposed on the first metal layer. The first metal layer is thicker than the second metal layer. A first region in which the first metal layer is not disposed is provided at an outer peripheral portion of an upper surface of the first graphite layer. The second metal layer covers the first metal layer and the first region of the upper surface of the first graphite layer.

### CROSS-REFERENCE TO RELATED APPLICATION

This application claims priority to Japanese Patent Application No. 2024-118740, filed on Jul. 24, 2024, the disclosure of which is hereby incorporated by reference in its entirety.

### TECHNICAL FIELD

The present disclosure relates to a submount and a method of producing the same, and a light-emitting device.

### BACKGROUND

An electronic device such as a light-emitting device includes, for example, a submount on which a light-emitting element is disposed. Submounts are required to have high thermal conductivity to dissipate heat generated by light-emitting elements. For example, a submount includes a support layer and a graphite layer disposed on the support layer, and a light-emitting element is disposed on the graphite layer. (See, for example, Japanese Patent Publication No. 2023-088042.

### SUMMARY

An object of the present disclosure is to provide a submount with good heat dissipation and a method of producing the same. In addition, an object of the present disclosure is to provide a light-emitting device including this submount.

A submount according to an embodiment of the present disclosure includes: a support layer; a first graphite layer disposed on the support layer; a first metal layer disposed on the first graphite layer; and a second metal layer disposed on the first metal layer, wherein the first metal layer is thicker than the second metal layer, a first region in which the first metal layer is not disposed is provided at an outer peripheral portion of an upper surface of the first graphite layer, and the second metal layer covers the first metal layer and the first region of the upper surface of the first graphite layer.

A method of producing a submount according to an embodiment of the present disclosure includes: providing a layered body including a support layer and a first graphite layer disposed on the support layer; disposing a first metal layer on the first graphite layer; forming a first groove portion at which the first graphite layer is not covered by the first metal layer by removing a portion of the first metal layer; disposing a second metal layer thinner than the first metal layer on the first metal layer and on the first graphite layer not covered with the first metal layer in the first groove portion; and cutting the second metal layer and the layered body along the first groove portion.

A light-emitting device according to an embodiment of the present disclosure includes: a base member; the submount according to an embodiment of the present disclosure disposed on the base member; and a light-emitting element disposed on the second metal layer.

According to an embodiment of the present disclosure, a submount with good heat dissipation and a method of producing the same can be provided. In addition, a light-emitting device including this submount can be provided.

### BRIEF DESCRIPTION OF DRAWINGS

FIG. 1 is a schematic top view of a submount 10.

FIG. 2 is a schematic bottom view of the submount 10.

FIG. 3 is a schematic cross-sectional view of the submount 10 taken along a cross-sectional line III-III in FIG. 1.

FIG. 4 is a partially enlarged schematic perspective view of a first graphite layer.

FIG. 5A is a schematic cross-sectional view (1) exemplifying a method of producing the submount according to a first embodiment.

FIG. 5B is a schematic cross-sectional view (2) exemplifying the method of producing the submount according to the first embodiment.

FIG. 5C is a schematic cross-sectional view (3) exemplifying the method of producing the submount according to the first embodiment.

FIG. 5D is a schematic cross-sectional view (4) exemplifying the method of producing the submount according to the first embodiment.

FIG. 5E is a schematic cross-sectional view (5) exemplifying the method of producing the submount according to the first embodiment.

FIG. 6 is a schematic perspective view exemplifying a light-emitting device according to a second embodiment.

FIG. 7 is a schematic perspective view of the light-emitting device illustrated in FIG. 6, in a state in which a lid member is removed.

FIG. 8 is a schematic top view of the light-emitting device illustrated in FIG. 7.

FIG. 9 is a schematic cross-sectional view of the light-emitting device taken along a cross-sectional line IX-IX in FIG. 6.

FIG. 10 is a schematic enlarged view of a region surrounded by a broken line A in FIG. 9.

### DETAILED DESCRIPTIONS

Hereinafter, embodiments for carrying out the invention are described with reference to the drawings. Note that, in the following description, terms indicating a specific direction or position (for example, “upper,” “above,” “lower,” under,” “below,” and other terms related to those terms) are used as necessary. However, these terms are used to facilitate understanding of the invention with reference to the drawings, and the technical scope of the present invention is not excessively limited by the meaning of these terms.

The term “on” encompasses both a configuration in which a member is disposed directly on and in contact with another member and a configuration in which a member is disposed on another member with a space or an intervening member interposed therebetween. Also, the term “cover” in the present disclosure encompasses both a configuration in which a member directly covers and in contact with another member and a configuration in which a member covers another member with a space or an intervening member interposed therebetween. For example, when the term “upper surface” is used, the invention does not always have to be used so as to face upward. Portions having the same reference signs appearing in a plurality of drawings indicate identical or equivalent portions or members.

In the present disclosure, polygons such as triangles and quadrangles, having shapes in which the corners of the polygon are rounded, chamfered, beveled, coved, and the like, are referred to as polygons. A shape obtained by processing not only the corners (ends of a side) but also an intermediate portion of the side is similarly referred to as a polygon. That is, a shape that is partially processed while leaving the polygon as the base is included in the interpretation of the “polygon” described in the present disclosure.

The same applies not only to polygons but also to words representing specific shapes such as trapezoids, circles, protrusions, and recessions. The same applies when dealing with each side forming that shape. That is, even when processing is performed on a corner or an intermediate portion of a certain side, the interpretation of “side” includes the processed portion. When a “polygon” or a “side” not partially processed is to be distinguished from a processed shape, “strict” will be added to the description as in, for example, “strict quadrangle.”

The following embodiments exemplify submounts and the like for embodying the technical concept of the present invention, but the present invention is not limited to the description below. The dimensions, materials, shapes, relative arrangements, and the like of constituent elements described below are not intended to limit the scope of the present invention to those alone but are intended to provide an example, unless otherwise specified. The contents described in one embodiment can be applied to any of the other embodiments and modified examples. The sizes, the positional relationship, and the like of the members illustrated in the drawings may be exaggerated to clarify the explanation. Furthermore, to avoid excessive complication of the drawings, a schematic view in which some elements are not illustrated may be used, or an end view illustrating only a cutting surface may be used as a cross-sectional view.

### First Embodiment

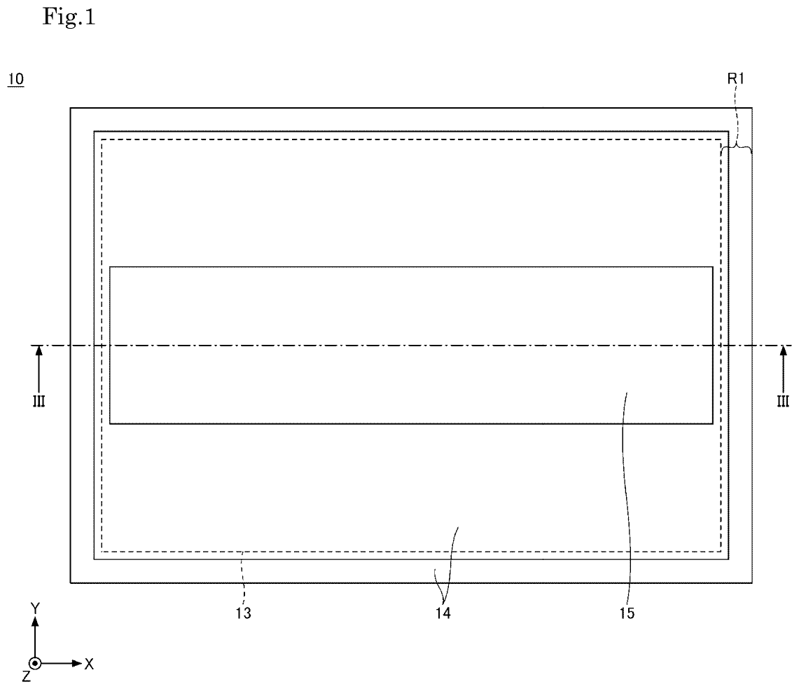

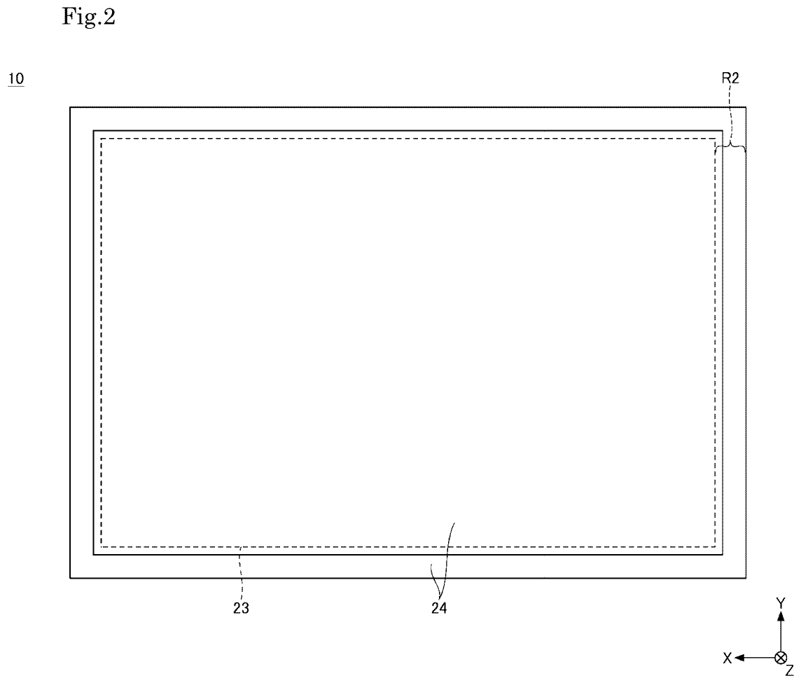

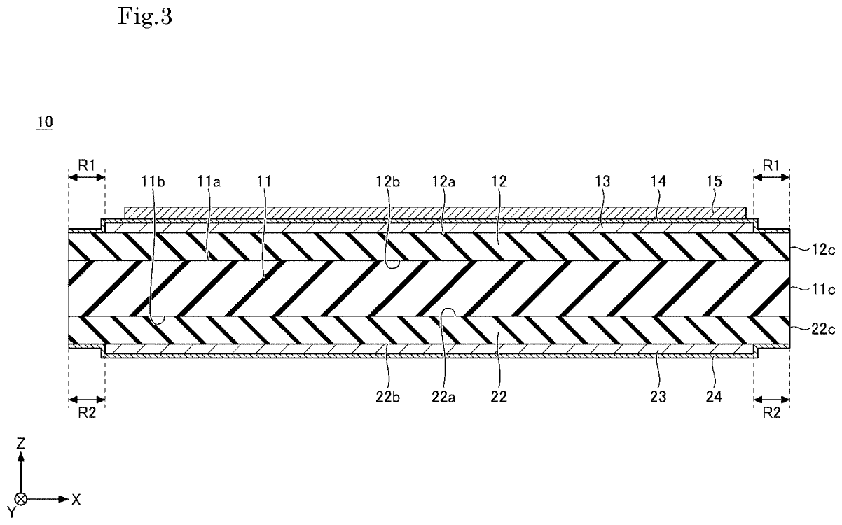

A submount 10 according to a first embodiment will now be described. FIGS. 1 to 3 are schematic drawings for describing an exemplary form of the submount 10. FIG. 1 is a schematic top view of the submount 10. FIG. 2 is a schematic bottom view of the submount 10. FIG. 3 is a schematic cross-sectional view of the submount 10 taken along the cross-sectional line III-III in FIG. 1.

Note that, in each of the drawings, an X-axis, a Y-axis, and a Z-axis, which are orthogonal to each other, are illustrated for reference, as necessary. A direction parallel to the X-axis is referred to as an X direction, a direction parallel to the Y-axis is referred to as a Y direction, and a direction parallel to the Z-axis is referred to as a Z direction. In addition, in the X direction, a direction in which an arrow is directed is referred to as a +X direction, and a direction opposite to the +X direction is referred to as a −X direction. In the Y direction, a direction in which an arrow is directed is referred to as a +Y direction, and a direction opposite to the +Y direction is referred to as a −Y direction. In the Z direction, a direction in which an arrow is directed is referred to as a +Z direction, and a direction opposite to the +Z direction is referred to as a −Z direction. However, these directions do not limit the orientation of the submount during use, and the orientation of the submount may be any chosen orientation.

### Submount 10

As exemplified in FIGS. 1 to 3, a submount 10 includes a support layer 11, a first graphite layer 12, a first metal layer 13, a second metal layer 14, a third metal layer 15, a second graphite layer 22, a fourth metal layer 23, and a fifth metal layer 24. Note that the submount 10 does not necessarily have to include the third metal layer 15, the second graphite layer 22, the fourth metal layer 23, and the fifth metal layer 24.

The length of the submount 10 in the X direction may be, for example, in a range from 0.3 mm to 5 mm. The length of the submount 10 in the Y direction may be, for example, in a range from 0.3 mm to 4 mm. The length of the submount 10 in the Z direction, that is, the thickness of the submount 10 may be, for example, in a range from 0.3 mm to 1.0 mm. The length of the submount 10 in the Z direction may be smaller than both the length of the submount 10 in the X direction and the length of the submount 10 in the Y direction.

The support layer 11 includes an upper surface 11a, a lower surface 11b that is a surface on the opposite side of the upper surface 11a, and one or a plurality of lateral surfaces 11c intersecting the upper surface 11a and the lower surface 11b. The one or the plurality of lateral surfaces 11c connect an outer edge of the upper surface 11a and an outer edge of the lower surface 11b. In the illustrated example, the upper surface 11a and the lower surface 11b are parallel to each other. The upper surface 11a and the lower surface 11b do not necessarily have to be parallel to each other. In the illustrated example, each lateral surface 11c is perpendicular to the upper surface 11a and the lower surface 11b. Each lateral surface 11c does not necessarily have to be perpendicular to the upper surface 11a or does not necessarily have to be perpendicular to the lower surface 11b. Note that the terms parallel and perpendicular used herein allow a difference of 5 degrees.

In the illustrated example, the support layer 11 is rectangular in a top view. In this case, both the upper surface 11a and the lower surface 11b of the support layer 11 are rectangular, and the support layer 11 includes four rectangular lateral surfaces 11c. The support layer 11 does not necessarily have to be rectangular in a top view. A rectangular shape may include a square shape unless specifically described as excluding a square shape. The length of the support layer 11 in the Z direction (thickness of the support layer 11) is shorter than the length in the X direction and the length in the Y direction. The thickness of the support layer 11 may be, for example, in a range from 100 μm to 400 μm.

The support layer 11 may be formed of, for example, a ceramic. Specifically, the support layer 11 may be formed of at least one ceramic selected from the group consisting of AlN, SiC, silicon nitride, and alumina, for example. The ceramic may be, for example, a low temperature co-fired ceramic (LTCC). Alternatively, the support layer 11 may be formed of one metal selected from the group consisting of Ag, Cu, W, Au, Ni, Pt, and Pd or an alloy containing a plurality of the metals selected from this group.

The rigidity of the support layer 11 is higher than the rigidity of the first graphite layer 12. The thickness of the support layer 11 is greater than the thickness of the first graphite layer 12. In addition, the rigidity of the support layer 11 is higher than the rigidity of the second graphite layer 22. The thickness of the support layer 11 is greater than the thickness of the second graphite layer 22. The mechanical strength of the submount 10 can be improved by supporting the brittle first graphite layer 12 or the brittle second graphite layer 22 with the highly rigid and thick support layer 11.

The first graphite layer 12 includes an upper surface 12a, a lower surface 12b that is a surface on the opposite side of the upper surface 12a, and one or a plurality of lateral surfaces 12c intersecting the upper surface 12a and the lower surface 12b. The one or the plurality of lateral surfaces 12c connect an outer edge of the upper surface 12a and an outer edge of the lower surface 12b. In the illustrated example, the upper surface 12a and the lower surface 12b are parallel to each other. The upper surface 12a and the lower surface 12b do not necessarily have to be parallel to each other. In the illustrated example, each lateral surface 12c is perpendicular to the upper surface 12a and the lower surface 12b. Each lateral surface 12c does not necessarily have to be perpendicular to the upper surface 12a or does not necessarily have to be perpendicular to the lower surface 12b. The thickness of the first graphite layer 12 may be, for example, in a range from 50 μm to 200 μm.

The first graphite layer 12 is disposed on the support layer 11. The first graphite layer 12 may be disposed, for example, over the entire upper surface 11a of the support layer 11. Each lateral surface 12c of the first graphite layer 12 is not covered with the first metal layer 13 and the second metal layer 14. One lateral surface 12c of the first graphite layer 12 may be flush with one lateral surface 11c of the support layer 11. When there are a plurality of lateral surfaces 12c of the first graphite layer 12 and a plurality of lateral surfaces 11c of the support layer 11, there may be a plurality of sets each in which the lateral surface 12c of the first graphite layer 12 and the lateral surface 11c of the support layer 11 are flush with each other. In a case in which some of the lateral surfaces 12c of the first graphite layer 12 are respectively flush with some of the lateral surfaces 11c of the support layer 11, the remaining lateral surfaces 12c of the first graphite layer 12 do not necessarily have to be respectively flush with the remaining lateral surfaces 11c of the support layer 11. In the illustrated example, there are four sets each in which the lateral surface 12c of the first graphite layer 12 and the lateral surface 11c of the support layer 11 are flush with each other. In addition, in the illustrated example, at least a portion of the outer edge of the upper surface 11a of the support layer 11 coincides with the outer edge of the first graphite layer 12 in a top view.

In a case in which the light-emitting element 220 is disposed on the submount 10, the larger the region in which the lower surface 12b of the first graphite layer 12 and the upper surface 11a of the support layer 11 overlap with each other, the more efficiently the submount 10 can dissipate heat generated by the light-emitting element 220. From this viewpoint, it is preferable that the outer edge of the lower surface 12b of the first graphite layer 12 and the outer edge of the upper surface 11a of the support layer 11 coincide in a top view. In the illustrated example, the outer edge of the lower surface 12b of the first graphite layer 12 and the outer edge of the upper surface 11a of the support layer 11 coincide in the top view.

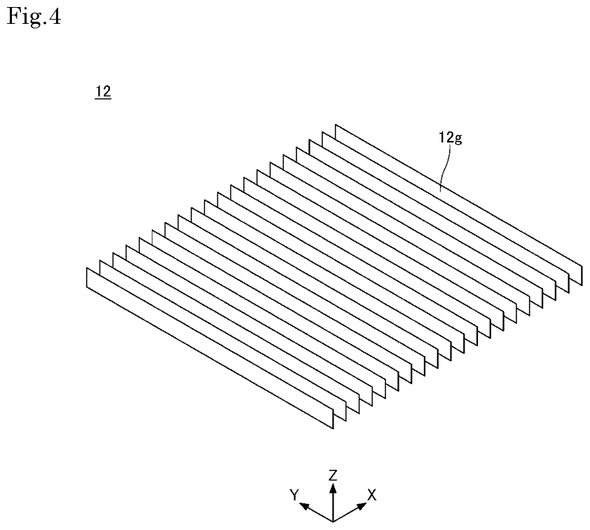

FIG. 4 is a partially enlarged schematic perspective view of the first graphite layer 12. As schematically illustrated in FIG. 4, the first graphite layer 12 includes a plurality of pieces of graphene 12g layered in the X direction. Each of the plurality of pieces of graphene extends in the YZ plane direction, and the extension (length) in the Y direction is greater than the extension (length) in the Z direction. Each piece of graphene 12g has a planar shape parallel to the YZ plane, and is configured by a honeycomb structure formed by covalent bonding of a plurality of carbon atoms. Two pieces of graphene 12g adjacent to each other in the X direction are bonded together by van der Waals forces. Actually, a distance between two adjacent pieces of graphene 12g in the X direction is approximately in a range from 0.3 nm to 0.4 nm, which is considerably narrow, but is exaggerated in the example illustrated in FIG. 4.

Thermal conduction carriers in each piece of graphene 12g are mainly phonons rather than electrons. Heat is more easily transferred in a plane of each piece of graphene 12g than between two pieces of graphene 12g adjacent to each other. Thus, the thermal conductivity of the first graphite layer 12 in the YZ plane direction is considerably high, and conversely, the thermal conductivity of the first graphite layer 12 in the X direction is not so high. Specifically, the thermal conductivity of the first graphite layer 12 in the YZ plane direction is, for example, 1700 W/mK, and the thermal conductivity in the X direction is, for example, 7 W/mK. As described above, the first graphite layer 12 has high anisotropy in thermal conductivity.

The first metal layer 13 is disposed on the first graphite layer 12. The first metal layer 13 is thicker than the second metal layer 14. The thickness of the first metal layer 13 may be, for example, in a range from 5 μm to 100 μm. It is preferably in a range from 5 μm to 50 μm. By setting the thickness to 5 μm or more, absorption of ultrasonic waves by the first graphite layer 12 at the time of ultrasonic bonding of a wiring 270 can be reduced, and the bonding strength with the wiring 270 can be increased. In addition, by setting the thickness to 50 μm or less, heat dissipation to the first graphite layer 12 is increased, and a first groove portion 13x is easily formed at the time of manufacturing. The first metal layer 13 may contain, for example, copper. The first metal layer 13 is not disposed over the entire upper surface 12a of the first graphite layer 12. Specifically, the first metal layer 13 is not disposed in a first region R1 of an outer peripheral portion of the upper surface 12a of the first graphite layer 12. In other words, the first region R1 in which the first metal layer 13 is not disposed is provided at the outer peripheral portion of the upper surface 12a of the first graphite layer 12.

Here, the outer peripheral portion of the upper surface 12a of the first graphite layer 12 is the outer edge of the upper surface 12a and a region in the vicinity thereof. It can be said that the outer peripheral portion is, for example, a region of the upper surface 12a at a distance of 100 μm or less from the outer edge of the upper surface 12a. In addition, for example, in the upper surface 12a, this region can be referred to as a region whose distance from the outer edge of the upper surface 12a is 30 μm or less.

The first region R1 is a region including at least one side and the vicinity thereof among one or a plurality of sides forming the outer edge(s) of the first graphite layer 12 in a top view. The first region R1 may be a region including at least two opposing sides and the vicinity thereof among the plurality of sides forming the outer edges of the first graphite layer 12 in a top view. The first region R1 may be a region including at least two opposing first sides and the vicinity thereof and two opposing second sides and the vicinity thereof among the plurality of sides forming the outer edges of the first graphite layer 12 in a top view. The first region R1 may be the outer peripheral portion of the upper surface 12a.

In a top view, the outer edge of the upper surface 12a of the first graphite layer 12 is within a range of a predetermined distance from an outer edge of the first metal layer 13. The range of the predetermined distance is, for example, 100 μm or less. Further, for example, the range of the predetermined distance is in a range from 20 μm to 100 μm. The submount 10 can be stably produced by setting the distance from the outer edge of the first metal layer 13 to the outer edge of the upper surface 12a to 20 μm or more in a top view. By setting the distance to 100 μm or less, the entire surface of the first graphite layer 12 can be efficiently utilized for heat dissipation.

In a top view, a portion of the outer edge of the first graphite layer 12 is positioned within a range of 100 μm or less from at least one side among one or a plurality of sides forming the outer edge(s) of the first metal layer 13. In a top view, a portion of the outer edge of the first graphite layer 12 is positioned within a range of 100 μm or less from each of at least two opposing sides among the plurality of sides forming the outer edges of the first metal layer 13.

In a top view, an area of the first metal layer 13 is preferably larger than an area of the first region R1. In a top view, the ratio of the area of the lower surface of the first metal layer 13 to the area of the upper surface 12a of the first graphite layer 12 is, for example, 70%. In addition, this ratio is preferably 90% or more. By disposing the first metal layer 13 having a relatively large thickness over a wide area, when the first graphite layer 12 is cut, because the first graphite layer 12 is protected by the first metal layer 13, the occurrence of large chipping that starts from the cut portion of the first graphite layer 12 to the portion immediately below the first metal layer 13 can be reduced.

In a case in which the first graphite layer 12 has, for example, a rectangle shape with long sides and short sides in a top view, the first region R1 includes at least the short side and the vicinity thereof. In this case, the first region R1 is provided at least along the short side. The first region R1 may include only one of the opposing short sides and the vicinity thereof, or may include both sides and the vicinity thereof. In addition, the first region R1 may include only one of the opposing long sides and the vicinity thereof, or may include both sides and the vicinity thereof. The first region R1 may be provided along only any one of these sides included in the first graphite layer 12, or may be provided along all the sides. In the illustrated example, the first region R1 is provided in an annular shape on the upper surface 12a of the first graphite layer 12. By providing the first region R1 in an annular shape at the outer peripheral portion of the upper surface 12a of the first graphite layer 12, burrs caused by cutting of the first metal layer 13 are not generated along all sides of the first graphite layer 12.

The second metal layer 14 is disposed on the first metal layer 13. The second metal layer 14 is disposed on the upper surface 12a side of the first graphite layer 12. The second metal layer 14 covers the first metal layer 13 and the first region R1 of the upper surface 12a of the first graphite layer 12. The second metal layer 14 may cover lateral surfaces of the first metal layer 13. The second metal layer 14 covers an outer peripheral portion of the first graphite layer 12. The second metal layer 14 covers a portion of the upper surface 12a of the first graphite layer 12 exposed from the first metal layer 13.

The thickness of the second metal layer 14 is smaller than the thickness of the first metal layer 13. The first metal layer 13 may be thicker than the second metal layer 14 by 10 μm or more. The first metal layer 13 may be thicker than the second metal layer 14 by 20 μm or more. The thickness of the second metal layer 14 may be, for example, in a range from 0.3 μm to 10 μm. The ratio of the thickness of the second metal layer 14 to the thickness of the first metal layer 13 may be, for example, in a range from 2% to 10%. The second metal layer 14 may contain, for example, at least one metal selected from the group consisting of titanium, platinum, and gold.

A third metal layer 15 may be further disposed on the second metal layer 14. Specifically, the third metal layer 15 can be used as a bonding material in a case in which the light-emitting element 220 is disposed on the second metal layer 14. The third metal layer 15 is disposed at a position overlapping a portion of the second metal layer 14 in a top view. In other words, the third metal layer 15 is not disposed over the entire second metal layer 14 in a top view. One or a plurality of third metal layers 15 is disposed on the second metal layer 14. The third metal layer 15 is disposed at a position overlapping the first metal layer 13 in a top view. The third metal layer 15 does not overlap the outer edge of the first graphite layer 12 in a top view. The third metal layer 15 is not disposed at a position not overlapping the first metal layer 13 in a top view.

The thickness of the third metal layer 15 may be, for example, in a range from 1 μm to 10 μm. The third metal layer 15 may be formed of, for example, at least one alloy selected from the group consisting of AuSn, SnCu, SnAg, and SnAgCu. Alternatively, the third metal layer 15 may be formed of at least one alloy selected from the group consisting of a gold brazing material, a silver brazing material, and a copper brazing material. Alternatively, the third metal layer 15 may be formed of a metal including at least one type of particles selected from the group consisting of Ag particles, Cu particles, and Au particles.

In a case in which the third metal layer 15 is formed from AuSn or the like, high adhesion cannot be obtained when the first metal layer 13 is copper. Because a gold layer or the like having better adhesion to the third metal layer 15 than the first metal layer 13 is provided on the first metal layer 13, the adhesion between the first metal layer 13 and the third metal layer 15 can be increased.

The second graphite layer 22 includes an upper surface 22a, a lower surface 22b that is a surface on the opposite side of the upper surface 22a, and one or a plurality of lateral surfaces 22c intersecting the upper surface 22a and the lower surface 22b. The one or the plurality of lateral surfaces 22c connect an outer edge of the upper surface 22a and an outer edge of the lower surface 22b. In the illustrated example, the upper surface 22a and the lower surface 22b are parallel to each other. The upper surface 22a and the lower surface 22b do not necessarily have to be parallel to each other. In the illustrated example, each of the lateral surfaces 22c is perpendicular to the upper surface 22a and the lower surface 22b. Each of the lateral surfaces 22c does not necessarily have to be perpendicular to the upper surface 22a or does not necessarily have to be perpendicular to the lower surface 22b. The thickness of the second graphite layer 22 may be, for example, in a range from 50 μm to 200 μm. The thickness of the second graphite layer 22 and the thickness of the first graphite layer 12 may be the same or different. The second graphite layer may be the same graphite layer as the first graphite layer.

The second graphite layer 22 is disposed below the support layer 11. The second graphite layer 22 may be disposed, for example, over the entire lower surface 11b of the support layer 11. Each lateral surface 22c of the second graphite layer 22 is not covered with the fourth metal layer 23 and the fifth metal layer 24. One lateral surface 22c of the second graphite layer 22 may be flush with one lateral surface 11c of the support layer 11. In a case in which there are a plurality of lateral surfaces 22c of the second graphite layer 22 and a plurality of lateral surfaces 11c of the support layer 11, there may be a plurality of sets each in which the lateral surface 22c of the second graphite layer 22 and lateral surface 11c of the support layer 11 are flush with each other. In the case in which some of the lateral surfaces 22c of the second graphite layer 22 are respectively flush with some of the lateral surfaces 11c of the support layer 11, the remaining lateral surfaces 22c of the second graphite layer 22 do not necessarily have to be respectively flush with the remaining lateral surfaces 11c of the support layer 11. In the illustrated example, there are four sets each in which the lateral surface 22c of the second graphite layer 22 and the lateral surface 11c of the support layer 11 are flush with each other. In addition, in the illustrated example, the outer edge of the lower surface 11b of the support layer 11 coincides with an outer edge of the second graphite layer 22 in a bottom view. Similar to the first graphite layer 12, the second graphite layer 22 includes a plurality of pieces of graphene layered in the X direction.

In a case in which the light-emitting element 220 is disposed on the submount 10, the larger the region in which the upper surface 22a of the second graphite layer 22 and the lower surface 11b of the support layer 11 overlap with each other, the more efficiently the submount 10 can dissipate heat generated by the light-emitting element 220. From this viewpoint, it is preferable that an outer edge of the upper surface 22a of the second graphite layer 22 and the outer edge of the lower surface 11b of the support layer 11 coincide with each other in a bottom view. In the illustrated example, the outer edge of the upper surface 22a of the second graphite layer 22 and the outer edge of the lower surface 11b of the support layer 11 coincide with each other in a top view.

The fourth metal layer 23 is disposed below the second graphite layer 22. The fourth metal layer 23 is thicker than the fifth metal layer 24. The thickness of the fourth metal layer 23 may be the same as or different from the thickness of the first metal layer 13. The fourth metal layer 23 may be, for example, formed of a metal material identical to that of the first metal layer 13. For example, when the first metal layer 13 is a copper plating layer, the fourth metal layer 23 may also be a copper plating layer. Note that, the fourth metal layer 23 may be formed of a material different from that of the first metal layer 13. The fourth metal layer 23 is not disposed over the entire lower surface 22b of the second graphite layer 22. Specifically, the fourth metal layer 23 is not disposed in a second region R2 of an outer peripheral portion of the lower surface 22b of the second graphite layer 22. In other words, the second region R2 in which the fourth metal layer 23 is not disposed is provided at the outer peripheral portion of the lower surface 22b of the second graphite layer 22.

Here, the outer peripheral portion of the lower surface 22b of the second graphite layer 22 is the outer edge of the lower surface 22b and a region in the vicinity thereof. It can be said that the outer peripheral portion is, for example, a region of the lower surface 22b at a distance of 100 μm or less from the outer edge of the lower surface 22b. In addition, it can be said that, in the lower surface 22b, the region is, for example, a region at a distance of 30 μm or less from the outer edge of the lower surface 22b.

In a bottom view, the outer edge of the lower surface 22b of the second graphite layer 22 is within a range of a predetermined distance from an outer edge of the fourth metal layer 23. The predetermined distance is, for example, 100 μm or less. Further, for example, the range of the predetermined distance is in a range from 20 μm to 100 μm. The submount 10 can be stably produced by setting the distance from the outer edge of the fourth metal layer 23 to the outer edge of the lower surface 22b to 20 μm or more in a bottom view. By setting this distance to 100 μm or less, the entire surface of the second graphite layer 22 can be efficiently utilized for heat dissipation.

In a bottom view, the outer edge of a portion of the second graphite layer 22 is positioned within a range of 100 μm or less from at least one side among one or a plurality of sides forming the outer edge of the fourth metal layer 23. In a bottom view, the outer edge of a portion of the second graphite layer 22 is positioned within a range of 100 μm or less from each of at least two opposing sides among the plurality of sides forming the outer edge of the fourth metal layer 23.

In a bottom view, an area of the fourth metal layer 23 is preferably larger than an area of the second region R2. In a bottom view, the ratio of an area of the lower surface of the fourth metal layer 23 to an area of the lower surface 22b of the second graphite layer 22 is, for example, 70%. In addition, this ratio is preferably 90% or more. By disposing the fourth metal layer 23 having a relatively large thickness over a wide area, when the second graphite layer 22 is cut, because the second graphite layer 22 is protected by the fourth metal layer 23, the occurrence of large chipping that starts from the cut portion of the second graphite layer 22 to the portion immediately above the fourth metal layer 23 can be reduced.

In a case in which the second graphite layer 22 has, for example, a rectangle shape with long sides and short sides in a bottom view, the second region R2 is preferably provided in an annular shape along the long sides and the short sides. The second region R2 may be provided, for example, at a position overlapping the first region R1 in a top view. A width of the second region R2 may be, for example, the same as or similar to a width of the first region R1. The width of the second region R2 may be different from the width of the first region R1. By providing the second region R2 in an annular shape at the outer peripheral portion of the lower surface 22b of the second graphite layer 22, burrs caused by cutting of the fourth metal layer 23 are not generated along all sides of the second graphite layer 22.

The fifth metal layer 24 is disposed below the fourth metal layer 23. The fifth metal layer 24 is disposed on the lower surface 22b side of the second graphite layer 22. The fifth metal layer 24 covers the fourth metal layer 23 and the second region R2 of the lower surface 22b of the second graphite layer 22. The fifth metal layer 24 may cover lateral surfaces of the fourth metal layer 23. The fifth metal layer 24 covers the outer peripheral portion of the second graphite layer 22. The fifth metal layer 24 covers a portion of the lower surface 22b of the second graphite layer 22 exposed from the fourth metal layer 23.

The thickness of the fifth metal layer 24 is smaller than the thickness of the fourth metal layer 23. The fourth metal layer 23 may be thicker than the fifth metal layer 24 by 10 μm or more. The fourth metal layer 23 may be thicker than the fifth metal layer 24 by 20 μm or more. The thickness of the fifth metal layer 24 may be, for example, in a range from 0.3 μm to 10 μm. The ratio of the thickness of the fifth metal layer 24 to the thickness of the fourth metal layer 23 may be, for example, in a range from 2% to 10%. The thickness of the fifth metal layer 24 may be, for example, the same as or similar to that of the second metal layer 14. The thickness of the fifth metal layer 24 may be different from the thickness of the second metal layer 14. For example, the fifth metal layer 24 may be formed of a metal material identical to that of the second metal layer 14. The fifth metal layer 24 may be formed of a material different from the second metal layer 14.

### Method of Producing Submount 10

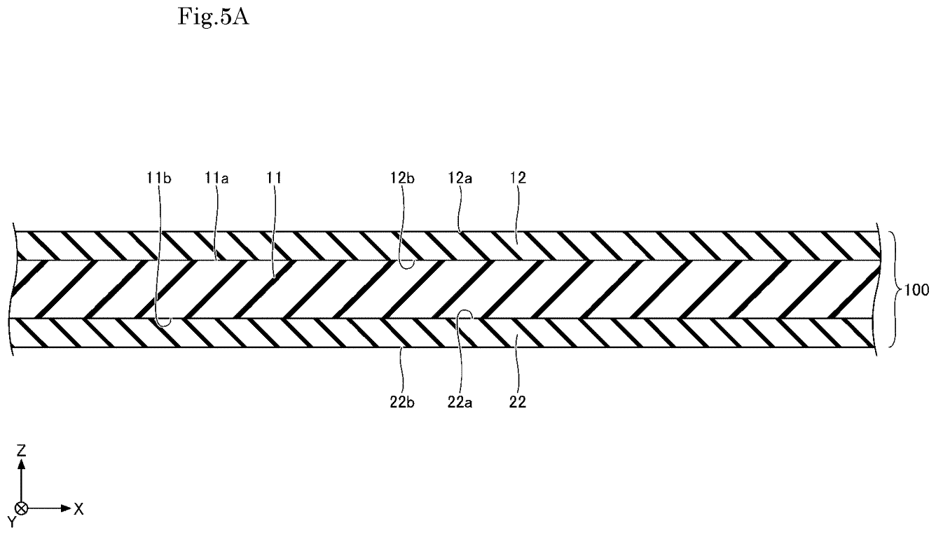

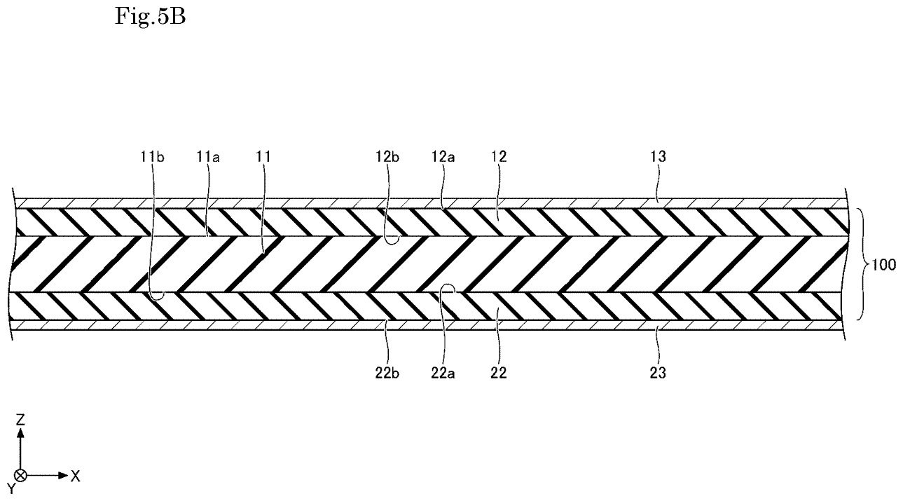

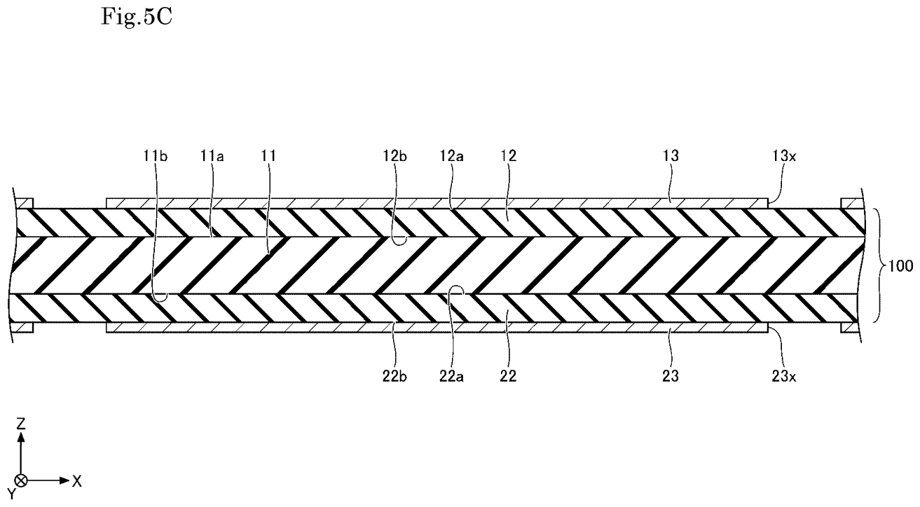

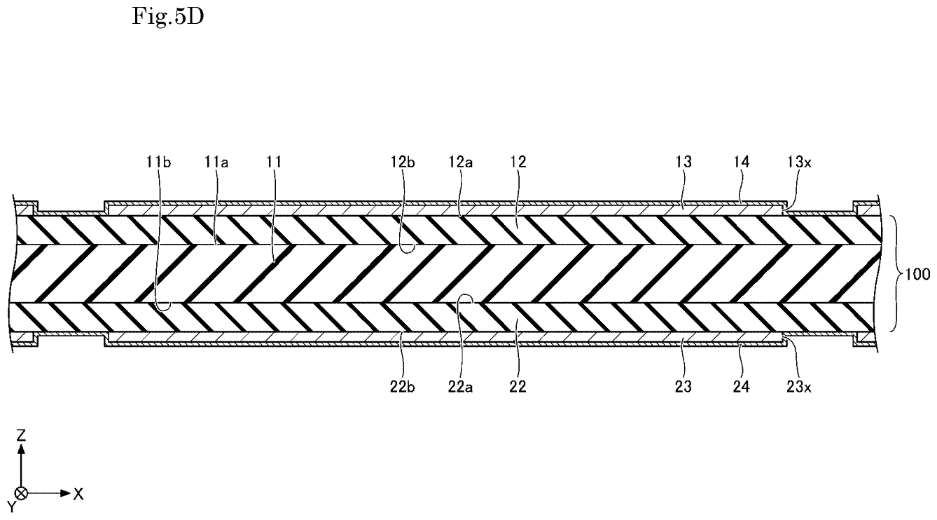

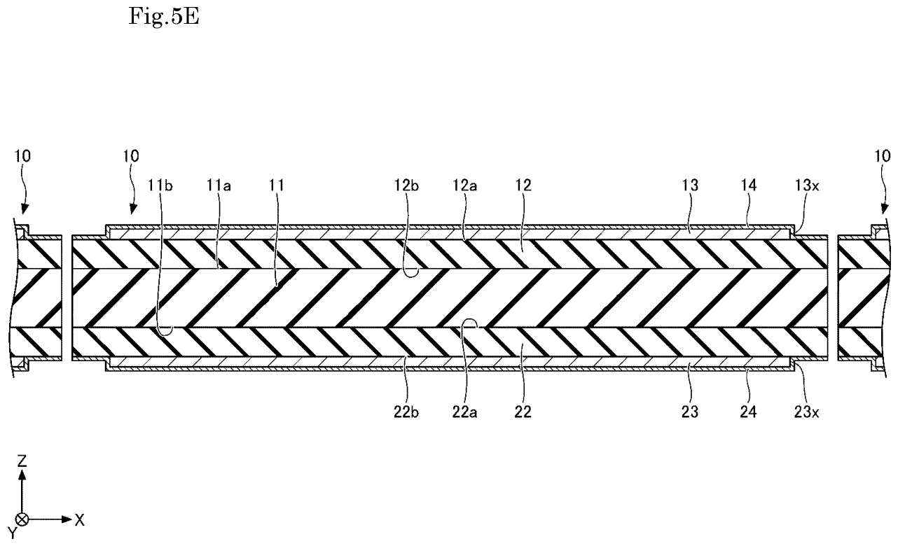

A method of producing the submount 10 according to a first embodiment is described with reference to FIGS. 5A to 5E. FIGS. 5A to 5E are schematic cross-sectional views exemplifying the method of producing the submount according to the first embodiment.

Step of Providing Layered body

First, as illustrated in FIG. 5A, a layered body 100 including the support layer 11, the first graphite layer 12 disposed on the support layer 11, and the second graphite layer 22 disposed below the support layer 11 is provided.

Specifically, first, graphite for forming the first graphite layer 12 and the second graphite layer 22 is provided and cut into a required size. The graphite is obtained by layering a plurality of graphene sheets. Similar to each piece of graphene 12g illustrated in FIG. 4, each graphene sheet constituting the graphite has a honeycomb structure formed by covalent bonding of a plurality of carbon atoms. Two graphene sheets adjacent to each other are bonded by van der Waals forces the same as or similar to the two pieces of graphene 12g adjacent to each other illustrated in FIG. 4.

Subsequently, the graphite is disposed above and below the support layer 11 and bonded thereto. Thus, the layered body 100 including the support layer 11, the first graphite layer 12 disposed above the support layer 11, and the second graphite layer 22 disposed below the support layer 11 is formed. That is, the graphite disposed above the support layer 11 is the first graphite layer 12, and the graphite disposed below the support layer 11 is the second graphite layer 22. Each piece of graphite and the support layer 11 are bonded to each other by, for example, room temperature bonding. Specifically, the upper surface 11a and the lower surface 11b of the support layer 11, the lower surface 12b of the first graphite layer 12, and the upper surface 22a of the second graphite layer 22 are polished, and the opposing surfaces are bonded to each other by an intermolecular force at room temperature. When necessary, the upper surface 12a of the first graphite layer 12 and the lower surface 22b of the second graphite layer 22 may be polished to be thinned.

### Step of Disposing First Metal Layer 13 and Fourth Metal Layer 23

Subsequently, as illustrated in FIG. 5B, the first metal layer 13 is disposed on the first graphite layer 12. Further, the fourth metal layer 23 is disposed below the second graphite layer 22. The first metal layer 13 and the fourth metal layer 23 may be disposed by, for example, plating, sputtering, vapor deposition, or the like.

Note that, in a case in which the adhesion between the first metal layer 13 and the first graphite layer 12 is low, a metal layer formed of a material different from that of the first metal layer 13 may be disposed between the first metal layer 13 and the first graphite layer 12. For example, in a case in which copper is plated as the first metal layer 13, adhesion can be improved by disposing a nickel layer having the thickness of several μm to approximately 30 μm between the first metal layer 13 and the first graphite layer 12. The same applies to the case in which the adhesion between the fourth metal layer 23 and the second graphite layer 22 is low.

### Step of Forming First Groove Portion 13x and Second Groove Portion 23x

Subsequently, as illustrated in FIG. 5C, a portion of the first metal layer 13 is removed to form the first groove portion 13x in which the first graphite layer 12 is not covered by the first metal layer 13. A portion of the upper surface 12a of the first graphite layer 12 is exposed from the first groove portion 13x. The lateral surfaces of the first metal layer 13 exposed by forming the first groove portion 13x become lateral surfaces of the submount 10. In addition, a portion of the fourth metal layer 23 is removed to form the second groove portion 23x in which the second graphite layer 22 is not covered by the fourth metal layer 24 in a bottom view. The lower surface 22b of the second graphite layer 22 is exposed from the second groove portion 23x. Lateral surfaces of the second metal layer 14 exposed by forming the second groove portion 23x become the lateral surfaces of the submount 10. For example, the first groove portion 13x and the second groove portion 23x may be formed in a lattice pattern in the X direction and the Y direction in a top view. The first groove portion 13x and the second groove portion 23x may be formed by etching, for example. For example, in the structure illustrated in FIG. 5B, the first groove portion 13x and the second groove portion 23x may be formed at the same time by forming a mask in a region other than the region in which the first groove portion 13x and the second groove portion 23x are formed and immersing the structure in an etching solution. Note that widths of the first groove portion 13x and the second groove portion 23x are determined in consideration of the widths of the first region R1 and the second region R2 and the widths to be removed by a blade or the like at the time of cutting.

### Step of Disposing Second Metal Layer 14 and Fifth Metal Layer 24

Subsequently, as illustrated in FIG. 5D, the second metal layer 14 thinner than the first metal layer 13 is disposed above the first metal layer 13 and above the portion of the first graphite layer 12 not covered with the first metal layer 13 in the first groove portion 13x. In addition, the fifth metal layer 24 thinner than the fourth metal layer 23 is disposed below the fourth metal layer 23 and below the portion of the second graphite layer 22 that is not covered with the fourth metal layer 23 in the second groove portion 23x. The second metal layer 14 and the fifth metal layer 24 may be disposed by, for example, sputtering, plating, vapor deposition, or the like.

### Step of Cutting

Subsequently, as illustrated in FIG. 5E, the second metal layer 14, the layered body 100, and the fifth metal layer 24 are cut along the first groove portion 13x and the second groove portion 23x. As a result, the layered body 100, the second metal layer 14, and the fifth metal layer 24 are cut to form a plurality of submounts 10. Lateral surfaces of the layered body 100 exposed by this cutting, that is, the lateral surfaces 11c of the support layer 11, the lateral surfaces 12c of the first graphite layer 12, the lateral surfaces 22c of the second graphite layer 22, the lateral surfaces of the second metal layer 14, and lateral surfaces of the fifth metal layer 24 become the lateral surfaces of the submount 10. A blade or a laser, for example, can be used for the cutting. Note that, after the step of cutting or before the process of cutting, the third metal layer 15 may be disposed on the second metal layer 14, as necessary.

As described above, in the submount 10, the first metal layer 13 having a relatively large thickness is disposed in a portion other than the first region R1. As a result, when the first graphite layer 12 is cut, because the first graphite layer 12 is protected by the first metal layer 13, the occurrence of large chipping that starts from the cut portion of the first graphite layer 12 to the portion immediately below the first metal layer 13 can be reduced. In the production process of the submount 10, it can be said that the first region R1 is a region from the outer edge of the first metal layer 13 to the cutting edge in a top view. Similarly, the fourth metal layer 23 having a relatively large thickness is disposed in a portion other than the second region R2. Accordingly, when the second graphite layer 22 is cut, because the second graphite layer 22 is protected by the fourth metal layer 23, the occurrence of large chipping that starts from the cut portion of the second graphite layer 22 to the portion immediately above the fourth metal layer 23 can be reduced. In the production process of the submount 10, it can be said that the second region R2 is a region from the outer edge of the fourth metal layer 23 to the cutting edge in a bottom view.

Note that a target value of the cutting position may be approximately in a range from 10 μm to 20 μm from the outer edge of the first metal layer 13 in a top view. By bringing the cutting position closer to the outer edge of the first metal layer 13, an increase in chipping of the first graphite layer 12 that occurs in the first region R1 starting from the cut portion can be suppressed. Similarly, the target value of the cutting position can be set to approximately 10 μm to 20 μm from the outer edge of the fourth metal layer 23 in a bottom view. By bringing the cutting position closer to the outer edge of the fourth metal layer 23, an increase in chipping of the second graphite layer 22 that occurs in the second region R2 starting from the cut portion can be suppressed.

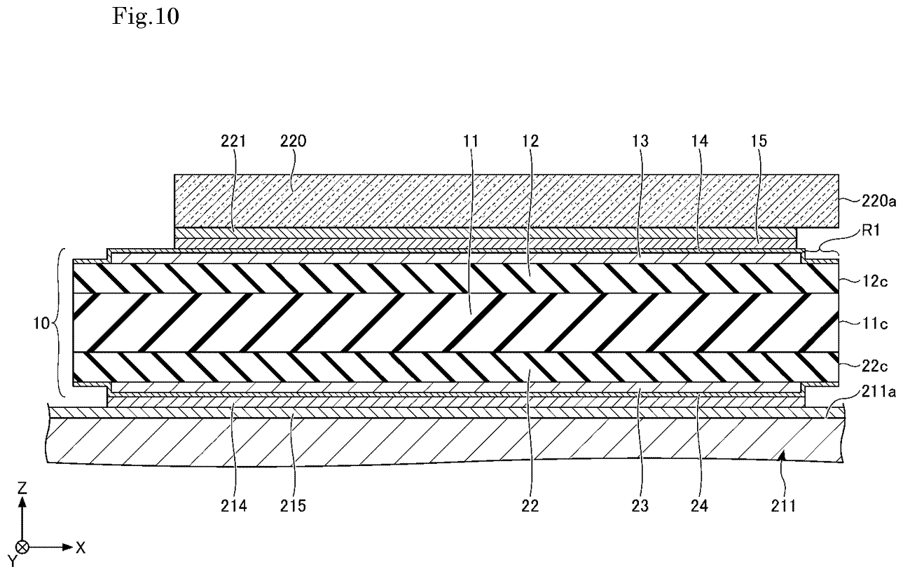

In addition, because the submount 10 is cut along the first region R1 and the second region R2 for singulation, the first metal layer 13 and the fourth metal layer 23, which are relatively thick, are not cut. Thus, burrs caused by the cutting of the first metal layer 13 and the fourth metal layer 23 are not generated in the cut portion and the vicinity thereof of the submount 10. For example, as illustrated in FIG. 10 to be described later, in a case in which the light-emitting element 220 is disposed on the submount 10, an emitting end surface 220a of the light-emitting element 220 is positioned near an end portion of the submount 10. Therefore, if there are burrs of the first metal layer 13 at the end portion or vicinity thereof of the submount 10, the light-emitting element 220 may be lifted due to the burrs, and cannot be disposed at the correct position in some cases. In addition, there is a possibility that the travel of light emitted from the light-emitting element 220 may be obstructed by the burrs. However, in the submount 10, because there are no burrs caused by cutting the first metal layer 13 at the end portion or vicinity thereof, such an issue does not occur.

In addition, when the submount 10 is disposed on a base member 211, if there are burrs of the fourth metal layer 23 at the end portion or vicinity thereof of the submount 10, there is a possibility that the submount 10 itself is lifted by the burrs, and cannot be disposed at the correct position in some cases. However, in the submount 10, such an issue does not occur because there are no burrs on the end portion or vicinity thereof of the fourth metal layer 23.

Note that because the second metal layer 14 and the fifth metal layer 24 are relatively thin, the size of burrs caused by the cutting of the second metal layer 14 and the fifth metal layer 24 can be reduced. When the burrs caused by the cutting of the second metal layer 14 are small, there is a low possibility that the burrs protrude from the upper surface of the second metal layer 14 positioned above the first metal layer 13. Therefore, there is substantially no influence on the arrangement of the light-emitting element 220 and the travel of light emitted from the light-emitting element 220. Similarly, when the burrs caused by the cutting of the fifth metal layer 24 are small, there is a low possibility that the burrs protrude from the lower surface of the fifth metal layer 24 positioned below the fourth metal layer 23. Therefore, the arrangement of the submount 10 itself is not affected.

In addition, in the method of producing the submount 10, a step of etching the first graphite layer 12 and the second graphite layer 22, which are difficult to etch, is not required. Accordingly, because the first graphite layer 12 and the second graphite layer 22 can be made thick, the thermal resistance of the first graphite layer 12 and the second graphite layer 22 can be reduced to improve heat dissipation of the submount 10.

### Second Embodiment

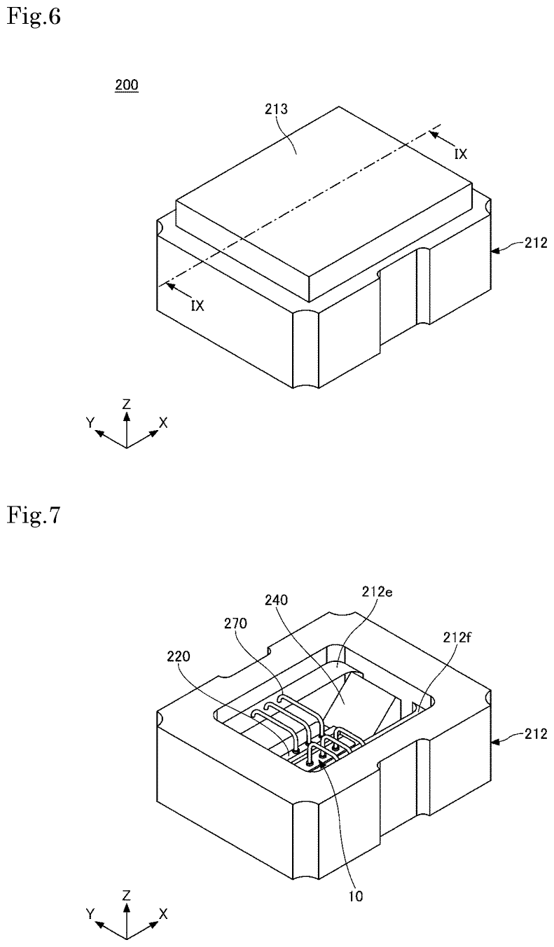

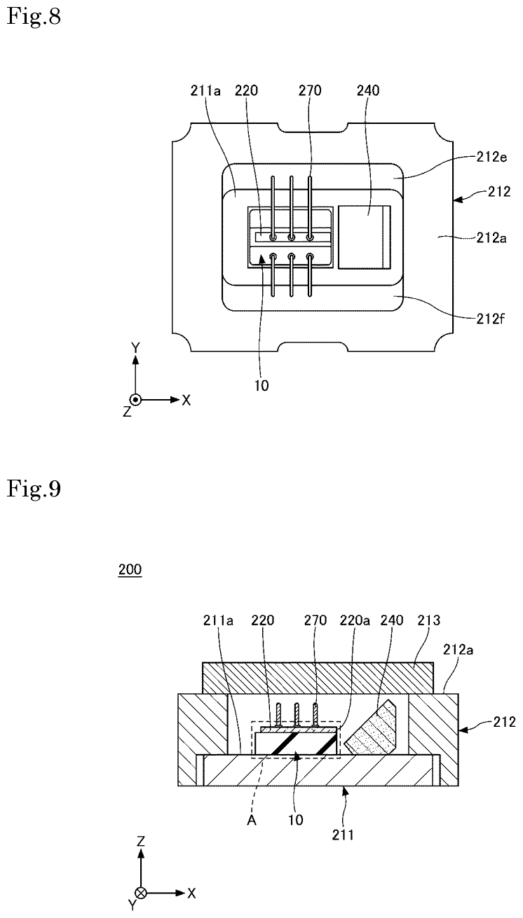

In a second embodiment, an example of a light-emitting device employing the submount according to the first embodiment will be described. FIG. 6 is a schematic perspective view exemplifying the light-emitting device according to the second embodiment. FIG. 7 is a schematic perspective view of the light-emitting device illustrated in FIG. 6, in a state in which a lid member is removed. FIG. 8 is a schematic top view of the light-emitting device illustrated in FIG. 7. FIG. 9 is a schematic cross-sectional view of the light-emitting device taken along a cross-sectional line IX-IX in FIG. 6. FIG. 10 is a schematic enlarged view of a region surrounded by a broken line A in FIG. 9. Note that, although the submount 10 is illustrated in a simplified manner in FIG. 9, the details thereof are as illustrated in FIG. 10.

As illustrated in FIGS. 6 to 10, a light-emitting device 200 according to the second embodiment includes the submount 10 according to the first embodiment, a base member 211, a frame portion 212, a lid member 213, a light-emitting element 220, a reflective member 240, and a wiring 270.

Each of the components of the light-emitting device 200 will be described.

### Base Member 211

The base member 211 includes an upper surface 211a and a lower surface. The base member 211 has a rectangular outer shape in a top view. This rectangular shape may be a rectangular shape with long sides and short sides. Note that the outer shape of the base member 211 in a top view does not necessarily have to be a rectangular shape. The base member 211 can be formed of, for example, a metal as a main material. For example, as the metal, copper, an alloy thereof, or the like can be used. Note that the base member 211 may be formed of a main material other than metal, and may be formed of, for example, a ceramic.

### Frame Portion 212

The frame portion 212 includes an upper surface 212a, a lower surface, one or a plurality of inner lateral surfaces, and one or a plurality of outer lateral surfaces. The frame portion 212 has a rectangular frame-like shape in a top view, for example. The frame portion 212 further includes step surfaces 212e and 212f positioned above the upper surface 211a of the base member 211 and below the upper surface 212a of the frame portion 212. The step surfaces 212e and 212f may be, for example, parallel with the upper surface 211a of the base member 211. In the illustrated example, each of the step surfaces 212e and 212f is provided along two inner lateral surfaces facing each other of the frame portion 212 in a top view.

One or a plurality of metal films may be provided on the step surfaces 212e and 212f. Further, the lower surface of the base member 211 and/or the lower surface of the frame portion 212 are provided with one or a plurality of metal films. The metal film provided on the step surfaces 212e and 212f can be electrically connected to the metal film provided on the lower surface of the base member 211 and/or the lower surface of the frame portion 212 through, for example, a via. For the metal film, Ni/Au (metal film layered in order of Ni, Au), Ti/Pt/Au (metal film layered in order of Ti, Pt, Au), and the like can be used, for example.

The frame portion 212 can be formed of, for example, a ceramic as a main material. For example, aluminum nitride, silicon nitride, aluminum oxide, or silicon carbide can be used as the ceramic.

The base member 211 and the frame portion 212 form a recessed shape which recessed from the upper surface 212a of the frame portion 212 in a direction to the upper surface 211a of the base member 211. The recessed shape is formed on the inner side of the outer shape of the frame portion 212 in a top view. In the illustrated example, the base member 211 and the frame portion 212 are separately formed and then bonded together. Note that the base member 211 and the frame portion 212 may be integrally formed using an identical main material.

### Lid Member 213

The lid member 213 includes an upper surface, a lower surface, and one or a plurality of lateral surfaces intersecting the upper surface and the lower surface. The one or the plurality of lateral surfaces connect an outer edge of the upper surface and an outer edge of the lower surface. The lid member 213 is, for example, a rectangular parallelepiped or a cube. In this case, both the upper surface and the lower surface of the lid member 213 have a rectangular shape, and the lid member 213 includes four of the lateral surfaces each having a rectangular shape.

However, the lid member 213 is not limited to a rectangular parallelepiped or a cube. That is, the lid member 213 is not limited to a rectangular shape in a top view, and can have any shape such as a circle, an oval, or a polygon.

The lid member 213 is supported by the frame portion 212. The lid member 213 is disposed above the upper surface 211a of the base member 211. An outer peripheral portion of the lower surface of the lid member 213 is bonded to, for example, the upper surface 212a of the frame portion 212. By bonding the lid member 213 to the frame portion 212, a sealed space surrounded by the base member 211, the frame portion 212, and the lid member 213 is formed.

The lid member 213 includes a light transmitting region that transmits light having a predetermined wavelength. The light transmitting region constitutes at least a portion of the upper surface and the lower surface of the lid member 213. For example, the light transmitting region of the lid member 213 can be formed by using sapphire as a main material. Sapphire is a material with relatively high transmittance and relatively high strength. Note that, as the main material of the light transmitting region of the lid member 213, in addition to sapphire, light-transmissive materials, such as quartz, silicon carbide, or glass, may be used. A portion other than the light transmitting region of the lid member 213 may be formed integrally with the light transmitting region using a material identical to that of the light transmitting region.

### Light-Emitting Element 220

In the illustrated example of the light-emitting device 200, one light-emitting element 220 is mounted. A plurality of the light-emitting elements may be mounted in the light-emitting device 200. The light-emitting element 220 is, for example, a semiconductor laser element. The semiconductor laser element may be an edge emitting laser or a vertical cavity surface emitting laser (VCSEL). The light-emitting element 220 is not limited to a semiconductor laser element and may be, for example, a light-emitting diode (LED) or an organic light-emitting diode (OLED).

A light-emitting element that emits visible light can be used as the light-emitting element 220. Examples of the light-emitting element that emits visible light include light-emitting elements that emit blue light, green light, and red light. Here, “light-emitting elements that emit blue light, green light, and red light” refer to light-emitting elements having emission peak wavelengths in a range from 405 nm to 494 nm, in a range from 495 nm to 570 nm, and in a range from 605 nm to 750 nm, respectively. Examples of the light-emitting element 220 that emits blue light or green light include a semiconductor laser element including a nitride semiconductor. As the nitride semiconductor, for example, GaN, InGaN, or AlGaN can be used. Examples of the light-emitting element 220 that emits red light include a semiconductor laser element including an InAlGaP-based, GaInP-based, GaAs-based, or AlGaAs-based semiconductor.

The emission peak of the light emitted from the light-emitting element 220 does not have to be limited to this. For example, the light emitted from the light-emitting element 220 may be visible light of a color other than the colors described above, and a light-emitting element that emits ultraviolet light, infrared light, or the like in addition to visible light may also be used. An upper surface and a lower surface of the light-emitting element 220 may be provided with a metal film.

### Reflective Member 240

The reflective member 240 includes a lower surface, a plurality of lateral surfaces, and a light reflective surface inclined relative to the lower surface. The plurality of lateral surfaces include two lateral surfaces opposing each other with the light reflective surface interposed therebetween. The light reflective surface preferably has a light reflectance of 90% or more with respect to the peak wavelength of irradiated light. The light reflective surface is, for example, a flat surface. The inclination angle of the light reflective surface with respect to the lower surface is in a range from 10 degrees to 80 degrees, for example, 45 degrees.

For the light reflective member 240, glass, metal, or the like can be used as a main material forming an outer shape thereof. The main material is preferably a heat-resistant material, and, for example, glass such as quartz and BK7 (borosilicate glass), metal such as aluminum, or Si can be used. The light reflective surface can be formed using, for example, a metal such as Ag or Al, or a dielectric multilayer film including, for example, Ta₂O₅/SiO₂, TiO₂/SiO₂, and Nb₂O₅/SiO₂.

### Wiring 270

The wiring 270 is formed from a conductor having a linear shape with bonding portions at both ends. In other words, the wiring 270 includes the bonding portions that are to be bonded to other components, at both ends of the linear portion. The wiring 270 is used for electrical connection between two components. For example, a metal wire can be used as the wiring 270. Examples of the metal include gold, aluminum, silver, copper, and tungsten.

### Light-Emitting Device 200

In the light-emitting device 200, the submount 10 and the reflective member 240 are disposed on the base member 211. In the example of FIG. 10, a fifth metal layer 24 of the submount 10 is bonded to a metal film 215 provided on the upper surface 211a of the base member 211 via a bonding portion 214. The bonding portion 214 is, for example, Au—Sn or the like. In addition, the metal film provided on the lower surface of the reflective member 240 is bonded to the metal film 215 provided on the upper surface 211a of the base member 211 via Au—Sn or the like.

The light-emitting element 220 is disposed on the submount 10. Specifically, the light-emitting element 220 is disposed on a second metal layer 14 of the submount 10. In the example of FIG. 10, a metal film 221 formed on the lower surface of the light-emitting element 220 and the second metal layer 14 of the submount 10 are bonded via a third metal layer 15. The light-emitting element 220 may be, for example, disposed such that an emitting end surface 220a faces a side of the light reflective surface of the reflective member 240.

Note that, in a case in which the light-emitting element 220 is the edge emitting laser, a first region R1 is provided at least in a direction in which the edge emitting laser emits light. This allows the travel of light emitted from the light-emitting element 220 not to be hindered by the burrs. For example, in the case of a light-emitting element that emits light in all directions, it is preferable to provide the first region R1 in a frame shape and suppress burrs in the entire outer peripheral portion of the submount 10.

The light-emitting element 220 is electrically connected to the metal film provided on the step surface 212e via the wiring 270. For example, one end of the wiring 270 is bonded to a metal film provided on the upper surface of the light-emitting element 220, and the other end of the wiring 270 is bonded to the metal film provided on the step surface 212e. The second metal layer 14 of the submount 10 is electrically connected to the metal film provided on the step surface 212f via wiring 270. For example, one end of the wiring 270 is bonded to the second metal layer 14, and the other end of the wiring 270 is bonded to the metal film provided on the step surface 212f. For the electrical connection between the light-emitting element 220 and an external power source, for example, the metal film provided on the lower surface of the base member 211 can be used.

The bonding between the wiring line 270 and the metal film and between the wiring line 270 and the second metal layer 14 may be performed by, for example, ultrasonic bonding. In a case in which the wiring 270 and the second metal layer 14 are ultrasonically bonded to each other, when the second metal layer 14 is directly formed on a first graphite layer 12, because the second metal layer 14 is thin, ultrasonic waves are absorbed by the first graphite layer 12 having low rigidity via the second metal layer 14. When ultrasonic waves are absorbed by the first graphite layer 12, it becomes difficult to bond the wiring 270 to the second metal layer 14.

However, in the submount 10, a first metal layer 13 thicker than the second metal layer 14 is disposed between the second metal layer 14 and the first graphite layer 12. Therefore, ultrasonic waves are less likely to be absorbed by the first graphite layer 12, and ultrasonic bonding between the wiring 270 and the second metal layer 14 is facilitated. From the viewpoint of making ultrasonic waves less likely to be absorbed by the first graphite layer 12, the thickness of the first metal layer 13 is preferably 5 μm or more.

The lid member 213 is disposed at the upper surface 212a of the frame portion 212. Specifically, the lid member 213 is supported by the upper surface 212a of the frame portion 212, and is disposed above the light-emitting element 220 surrounded by the frame portion 212. An outer peripheral portion of the lower surface of the lid member 213 is bonded to, for example, the upper surface 212a of the frame portion 212. For example, the metal film provided on the outer peripheral portion of the lower surface of the lid member 213 and the metal film provided on the upper surface 212a of the frame portion 212 are bonded and fixed via Au—Sn or the like.

By bonding the lid member 213 to the upper surface 212a of the frame portion 212, a sealed space at which the light-emitting element 220 and the reflective member 240 are disposed is formed. Further, this sealed space may be formed in a hermetically sealed state. For example, in a case in which the edge emitting laser is used as the light-emitting element 220, organic substances and the like are easily collected on the emitting end surface 220a. Therefore, the edge emitting laser is preferably disposed in a hermetically sealed space. In addition, in a case in which the light-emitting element 220 that emits light having wavelengths shorter than that of green light is used, organic substances and the like are easily collected on the emitting end surface 220a. Therefore, the light-emitting element 220 is preferably disposed in a hermetically sealed space. Therefore, in the case in which the edge emitting laser that emits light having a wavelength shorter than that of green light is used as the light-emitting element 220, it is particularly preferable to dispose the edge emitting laser in a hermetically sealed space.

The lid member 213 includes a light transmitting region through which the light reflected upward by the light reflective surface of the reflective member 240 is transmitted and emitted to the outside. That is, the light reflected from the light reflective surface of the reflective member 240 toward a side of the lid member 213 passes through the light transmitting region of the lid member 213 and is emitted to the outside of the light-emitting device 200. The entire lid member 213 may be the light transmitting region. It is preferable that the light transmitting region of the lid member 213 transmits 70% or more of the light reflected from the light reflective surface of the reflective member 240 to a side of the lid member 213.

The light-emitting device 200 can be used, for example, for an on-vehicle headlight. The light-emitting device 200 is not limited to the above and can be used for illumination, a projector, a head-mounted display, and a light source such as a backlight of other displays.

Although preferred embodiments and the like have been described in detail above, the invention is not limited to the above-described embodiments and the like. Various modifications and substitutions can be made to the above-described embodiments and the like without departing from the scope described in the claims.

What is claimed is:

1. A submount, comprising:
a support layer;
a first graphite layer disposed on the support layer;
a first metal layer disposed on the first graphite layer; and
a second metal layer disposed on the first metal layer, wherein:
the first metal layer is thicker than the second metal layer,
a first region in which the first metal layer is not disposed is provided at an outer peripheral portion of an upper surface of the first graphite layer, and
the second metal layer covers the first metal layer and the first region of the upper surface of the first graphite layer.

2. The submount according to claim 1, wherein a lateral surface of the first graphite layer is not covered with the first metal layer and the second metal layer.

3. The submount according to claim 1, wherein:
the first graphite layer has a rectangle shape with long sides and short sides in a top view, and
the first region is provided at least along the short sides.

4. The submount according to claim 1, wherein the first region has an annular shape at the outer peripheral portion of the upper surface of the first graphite layer.

5. The submount according to claim 1, wherein at least a portion of an outer edge of an upper surface of the support layer coincides with an outer edge of the first graphite layer in a top view.

6. The submount according to claim 1, further comprising a third metal layer disposed on the second metal layer.

7. The submount according to claim 1, wherein:
the support layer is formed of a ceramic,
the first metal layer contains copper, and
the second metal layer contains gold.

8. The submount according to claim 1, further comprising:
a second graphite layer disposed below the support layer;
a fourth metal layer disposed below the second graphite layer; and
a fifth metal layer disposed below the fourth metal layer, wherein:
the fourth metal layer is thicker than the fifth metal layer,
a second region in which the fourth metal layer is not disposed is provided at an outer peripheral portion of a lower surface of the second graphite layer, and
the fifth metal layer covers the fourth metal layer and the second region of the lower surface of the second graphite layer.

9. The submount according to claim 8, wherein:
the first metal layer and the fourth metal layer are formed of an identical metal material, and
the second metal layer and the fifth metal layer are formed of an identical metal material.

10. A light-emitting device, comprising:
a base member;
the submount according to claim 1 disposed on the base member; and
a light-emitting element disposed on the second metal layer.

11. The light-emitting device according to claim 10, wherein:
the light-emitting element is an edge emitting laser, and
the first region is provided on at least a side from which the edge emitting laser emits light.

12. A method of producing a submount, comprising:
providing a layered body comprising a support layer, and a first graphite layer disposed on the support layer;
disposing a first metal layer on the first graphite layer;
forming a first groove portion at which the first graphite layer is not covered by the first metal layer by removing a portion of the first metal layer;
disposing a second metal layer on the first metal layer and on a portion of the first graphite layer not covered with the first metal layer in the first groove portion, the second metal layer being thinner than the first metal layer; and
cutting the second metal layer and the layered body along the first groove portion.

13. The method of producing the submount according to claim 12, wherein:
in the providing of the layered body, the layered body further comprising a second graphite layer disposed below the support layer is provided,
the method further comprises, before the cutting:
disposing a fourth metal layer below the second graphite layer;
forming a second groove portion at which the second graphite layer is not covered by the fourth metal layer at a position overlapping the first groove portion viewed from an upper surface side of the first metal layer, the forming of the second groove portion being performed by removing a portion of the fourth metal layer; and
disposing a fifth metal layer below the fourth metal layer and below a portion of the second graphite layer not covered with the fourth metal layer in the second groove portion, the fifth metal layer being thinner than the fourth metal layer, wherein:
in the cutting, the second metal layer, the layered body, and the fifth metal layer are cut along the first groove portion and the second groove portion.
